(19) United States
(12) Patent Application Publication
(10) Pub. No.: US 2023/0335447 A1
(43) Pub. Date: Oct. 19, 2023

(54) Method for Manufacturing Metal Zero Layer

(71) Applicant: Shanghai Huali Integrated Circuit Corporation, Shanghai (CN)

(72) Inventors: Haibo Lei, Shanghai (CN); Wensheng Xu, Shanghai (CN)

(73) Assignee: Shanghai Huali Integrated Circuit Corporation, Shanghai (CN)

(21) Appl. No.: 18/175,878

(22) Filed: Feb. 28, 2023

(30) Foreign Application Priority Data
Apr. 14, 2022 (CN) 202210394299

(51) Int. Cl. H01L 29/66; H01L 21/8238

(52) U.S. Cl. CPC H01L 21/823814; H01L 21/823864; H01L 29/66545

(57) ABSTRACT

The application discloses a method for manufacturing a metal zero layer, comprising: step 1, providing a semiconductor substrate that undergoes a source and drain formation process of FEOL, wherein an inter-gate trench is formed in an area between dummy gate structures; step 2, forming a cut-off layer of metal zero layer in a selected area of the inter-gate trench; step 3, forming a metal zero layer in the inter-gate trench outside the cut-off layer of metal zero layer, and etching back the metal zero layer; step 4, forming a second oxide layer, the second oxide layer fully filling the inter-gate trench on the top surface of the metal zero layer, performing a planarization process to make the top surface of the second oxide layer level with the top surface of the dummy gate structure; and step 5, removing the dummy gate structure, and forming a second gate structure.

### CROSS-REFERENCE TO RELATED APPLICATIONS

This application claims the priority to Chinese patent application No. 202210394299.8, filed on Apr. 14, 2022, the disclosure of which is incorporated herein by reference in its entirety.

### TECHNICAL FIELD

The present application relates to a method for manufacturing a semiconductor integrated circuit, in particular to a method for manufacturing an active area metal zero layer (M0A).

### BACKGROUND

With the miniaturization of the process, the dimension of the middle of line (MOL) becomes increasingly small. At the technology node prior to the deep micro nano semiconductor process, the dimension and characteristics of a CMOS device have the greatest impact on the electrical property of device. With the miniaturization of the dimension, the contact resistance of the middle and back end of line and the resistance of the metal wiring impose an increasingly large impact on the device performance. In order to reduce the impact on the electrical property, the back end of line (BEOL) improves from the initial Al connection process to the Cu connection process, and the middle of line (MOL) improves from the W connection process to the Co connection process, making the resistance of the metal wiring increasingly low, and thus reducing the impact of the metal wiring on the device performance.

However, with the change of the metal connection process and the miniaturization of the dimension, the manufacturing process becomes increasingly complex and difficult, and the yield improvement becomes increasingly difficult. At the 7 nm process, the Co wiring process of a contact (CT) of the middle of line becomes one of the important reasons that limit the product yield. The prior art adopts the manner of electroplating with Co to replace the existing method of W CVD deposition in the 28/14 nm process. The process steps of electroplating with Co for forming a contact include: first depositing a barrier layer and a seed layer (B/S) on the bottom and sidewall of an oxide trench, and then filling the trench with Co by means of electroplating to ensure that there are no gaps and defects. Due to the activity of Co, after being polished by chemical mechanical polishing (CMP), Co needs to be quickly covered with a SiN protective layer so as to reduce oxidation and loss of Co. A subsequent process is a zero layer via (V0) process. The V0 process includes: depositing an oxide layer and forming an opening of a via by etching; then performing cleaning; and then depositing W using CVD or selective W method, so as to connect the middle of line and the back end of line. Due to the activity of Co, any etching, cleaning, and polishing process in the V0 process may lead to the loss of Co, resulting in oxidation or corrosion of Co. Therefore, particular cleaning and polishing processes are required in the subsequent process to protect Co and thus ensure the yield of the middle of line. The research and development cycle is long and of high difficulty, and the cost is extremely high.

FIG. 1 is a flowchart of an existing method for manufacturing a FinFET that includes a process of manufacturing a metal zero layer. The metal zero layer belongs to the middle of line. FIG. 1 also shows the front end of line (FEOL) between a dummy polysilicon gate and a metal gate before the middle of line and the back end of line for forming a via of the zero layer after the middle of line. FIGS. 2A-2H are schematic structural diagrams of device sections in steps of the manufacturing method corresponding to FIG. 1. The existing method for manufacturing a FinFET includes the following steps:

Step 101. Referring to FIG. 2A, a process loop of a dummy gate structure (not shown) is completed. The dummy gate structure is usually composed of a dummy gate dielectric layer and a dummy polysilicon (dummy poly) gate, so the process loop of the dummy gate structure is represented by poly loop. The dummy gate structure is formed on a semiconductor substrate. For the FinFET, a fin 101 is formed on the surface of the semiconductor substrate. The section in FIG. 2A is a section along the length direction of the fin 101, and the fin 101 is formed by performing patterned etching of the semiconductor substrate.

Generally, the dummy gate structure is defined by a hard mask layer.

Referring to FIG. 2A, a step of forming a spacer 108 on the side surface of the dummy gate structure is performed after formation of the dummy gate structure.

Step 102. A SiP loop is performed.

In order to improve the carrier mobility of the device, a stress enhancing structure such as an embedded epitaxial layer 102 is often formed to increase the stress in a channel area. A process of forming the embedded epitaxial layer 102 includes: forming a groove on two sides of the dummy gate structure in a self-aligned manner, and then filling the groove with the embedded epitaxial layer 102. Generally, both an NMOS and a PMOS are integrated on the semiconductor substrate. The embedded epitaxial layer 102 of the NMOS adopts SiP, and the SiP Loop is performed only in an area for forming the NMOS.

Step 103. A SiGe loop is performed.

Generally, the PMOS adopts the embedded SiGe epitaxial layer to improve the electron mobility in the channel area. The embedded epitaxial layer 102 of the PMOS adopts SiGe. The SiGe Loop is performed only in an area for forming the PMOS.

Step 104: Deposition (dep) and CMP of a zero interlayer dielectric (ILDO) 110 is performed, i.e., ILD0 Dep and CMP.

A step of forming a contact etch stop layer (CESL) 109 is performed before deposition of the zero interlayer dielectric 110. Then the zero interlayer dielectric 110 is deposited. After being deposited, the zero interlayer dielectric 110 fully fills a spacing area between the dummy gate structures and extends to the surface of a hard mask layer of the dummy gate structure outside the spacing area of the dummy gate structure. Subsequently, CMP is required to make the top surface of the zero interlayer dielectric 110 level with the top surface of the dummy gate structure, and the hard mask layer and the zero interlayer dielectric 110 over the top surface of the dummy gate structure are removed.

Step S105. The dummy gate structure is removed, i.e., dummy poly remove. Since the top surface of the dummy gate structure is exposed, after the CMP of the zero interlayer dielectric 110, the dummy polysilicon gate can be directly removed.

Step S106. A high dielectric constant metal gate (HKMG) is formed. The FinFET generally adopts a metal gate (MG), and the metal gate usually needs to be used in conjunction with a gate dielectric layer composed of a high dielectric constant (HK) material. A gate structure formed by stacking the gate dielectric layer including the high dielectric constant material layer and the metal gate is referred to as HKMG for short.

The HKMG is formed in an area where the dummy gate structure is removed. The HKMG includes: a high dielectric constant material layer 104, a bottom barrier metal (BBM) 105, a work function metal layer 106, and a metal conductive material layer 107.

Step S107. Metal gate CMP is performed, i.e., MG CMP. Generally, the material of the HKMG extends beyond the area where the dummy gate structure is removed, so CMP is required to remove the HKMG outside the area where the dummy gate structure is removed and make the surfaces of the HKMG and the zero interlayer dielectric 110 level with each other.

Next, the middle of line is performed to form an active area metal zero layer (M0A) and a gate metal zero layer (M0P), including the following steps:

Step S108. A process loop of cutting off the metal zero layer (cut of M0, M0C) is performed, i.e., an MOC loop.

In the existing method, an interlayer dielectric 111 corresponding to MOP needs to be formed first. MOC is formed by selectively etching the interlayer dielectric 111 or a stack layer of the zero interlayer dielectric 110 and interlayer dielectric 111. The selective etching needs to be performed separately in conjunction with an MOA loop and an MOP loop.

Step S109: The MOA loop is performed. Referring to FIG. 2B, an area for forming the M0A is defined. Then, a stack layer of the zero interlayer dielectric 110 and the interlayer dielectric 111 in the area for forming the MOA is selectively etched to form an opening 112 of the M0A. The area for forming the MOA corresponds to a top area of the embedded epitaxial layer 102 on two sides of the HKMG.

Step S110: The MOP loop is performed. Referring to FIG. 2B, an area for forming the MOP is defined. Then, a stack layer of the interlayer dielectric 111 in the area for forming the MOP is selectively etched to form an opening of the M0P. The area for forming the MOP is located in a top area of the HKMG.

Referring to FIG. 2C, after the opening 112 of the MOA and the opening of the MOP are formed, a barrier layer for blocking C0 and a seed layer of Co are formed, and then a C0 layer 113 is formed by electroplating.

Referring to FIG. 2D, CMP is performed. The C0 layer 113 is located only at the opening 112 of the MOA and the opening of the MOP and serves as the MOA and the MOP separately.

Step S111. A process loop for forming V0 is performed, that is, a V0 loop is performed, including the following:

Referring to FIG. 2E, an interlayer dielectric 115 through which a cap layer 114 and the V0 pass is formed.

Referring to FIG. 2F, an area for forming the V0 is defined, and then the interlayer dielectric 115 and the cap layer 114 are sequentially etched to form an opening 116 of the V0. FIG. 2F shows only a section of the area for forming the V0 at the top of the M0P, without showing a section of the area for forming the V0 at the top of the M0A. The etching of the opening 116 is divided into two steps, wherein the first step is etching the interlayer dielectric 115 using the cap layer 114 as a stop layer, and the second step is etching the remaining cap layer 114. Cleaning is required after the etching.

Referring to FIG. 2G, the opening 116 is filled with a metal layer 117, and the metal layer extends to the outside of the opening 116. The metal layer 117 usually adopts W, and W is usually grown by means of a CVD process.

Referring to FIG. 2H, CMP is performed to fully remove the metal layer 117 outside the opening 116, and the metal layer 117 retained in the opening 116 forms the zero layer via, i.e., V0.

### BRIEF SUMMARY

According to some embodiments in this application, a method for manufacturing a metal zero layer is disclosed in the following steps:
step 1, providing a semiconductor substrate that undergoes a source and drain formation process of the front end of line, wherein source and drain regions are formed on two sides of a dummy gate structure, a spacer is formed on the side surface of the dummy gate structure, a hard mask layer is formed on the top of the dummy gate structure, a plurality of the dummy gate structures are formed on the semiconductor substrate, and an inter-gate trench is formed in an area between the dummy gate structures;
step 2, forming a cut-off layer of metal zero layer in a selected area of the inter-gate trench, the cut-off layer of metal zero layer being composed of a dielectric layer;
step 3, forming a metal zero layer in the inter-gate trench outside the cut-off layer of metal zero layer, and etching back the metal zero layer to make the top surface of the metal zero layer lower than the top surface of the dummy gate structure;
step 4, forming a second oxide layer, the second oxide layer fully filling the inter-gate trench on the top surface of the metal zero layer, performing a planarization process to make the top surface of the second oxide layer level with the top surface of the dummy gate structure, and removing the hard mask layer on the top surface of the dummy gate structure; and
step 5, removing the dummy gate structure, and forming a second gate structure in an area where the dummy gate structure is removed, the second gate structure being formed by stacking a gate dielectric layer and a metal gate.

In some cases, in step 2, the dielectric layer of the cut-off layer of metal zero layer is a low-temperature oxide layer (LTO).

In some cases, in step 2, sub-steps of forming a patterned structure of the cut-off layer of metal zero layer include:
step 21, performing a first photolithography process, the first photolithography process including: sequentially applying a spin on carbon (SOC) layer and a photoresist, the spin on carbon layer fully filling the inter-gate trench, and performing exposure and development to pattern the photoresist;
step 22, performing a first etching process, the first etching fully removing the spin on carbon layer in an open area of the patterned photoresist and fully consuming the photoresist;
step 23, forming the low-temperature oxide layer to fully fill the inter-gate trench in an area where the spin on carbon layer is removed; and
step 24, performing a second etching process to remove the carbon coating in the inter-gate trench outside the low-temperature oxide layer.

In some cases, in step 2, step 21 to step 24 are performed circularly for a plurality of times.

In some cases, step 23 includes the following sub-steps:
performing a deposition process of the low-temperature oxide layer, the top surface of the low-temperature oxide layer being higher than the top surface of the inter-gate trench, and the low-temperature oxide layer extending outside the inter-gate trench; and
etching the low-temperature oxide layer, so that the low-temperature oxide layer remains only in the inter-gate trench and the top surface of the low-temperature oxide layer is level with the top surface of the inter-gate trench.

In some cases, in step 3, the material of the metal zero layer is Co.

The metal zero layer is formed by means of an electroplating process.

A step of forming a first barrier layer and a second seed layer is performed before formation of the metal zero layer, the first barrier layer being used to block Co diffusion of the metal zero layer.

In some cases, the metal zero layer, the first barrier layer, and the second seed layer are etched back by means of a wet etching process.

In some cases, after step 5, the method further includes:
forming a third oxide layer;
etching the third oxide layer in the selected area to form an opening of a zero layer via, the opening of the zero layer via being located at the top of the selected area on the top surface of the metal zero layer and being located at the top of the selected area on the top surface of the second gate structure; and
filling the opening of the zero layer via with a metal to form the zero layer via, the metal zero layer being in contact with the top zero layer via, and the metal gate being in contact with the top zero layer via.

In some cases, before formation of the third oxide layer, the method further includes a step of forming a cap layer, the cap layer being used to protect the metal zero layer and prevent the metal zero layer from oxidation and loss.

In a process of forming the opening of the zero layer via, after etching of the third oxide layer, the cap layer is etched so that the opening of the zero layer via exposes the bottom metal zero layer or the top surface of the metal gate.

In some cases, the material of the cap layer is silicon nitride.

In some cases, the metal material of the zero layer via includes tungsten.

In some cases, in step 5, the gate dielectric layer includes a high dielectric constant material layer.

The metal gate includes a metal work function layer and a metal conductive material layer which are stacked in sequence.

In some cases, the semiconductor substrate includes a silicon substrate.

In some cases, in step 1, the source and drain formation process further includes a step of forming an embedded epitaxial layer, and the source and drain regions are formed in the embedded epitaxial layer.

In some cases, in an area for forming a PMOS, the material of the embedded epitaxial layer includes SiGe; and in an area for forming an NMOS, the material of the embedded epitaxial layer includes SiP.

In some cases, in step 5, a thermal process in a process of forming the second gate structure is used to achieve a silicification reaction between the metal zero layer and bottom silicon and form a metal silicide.

In some cases, the PMOS and the NMOS are both FinFETs or GAAFETs.

In some cases, in step 1, the material of the spacer includes a low dielectric constant material.

A process of forming the spacer includes: growing a material layer of the spacer by means of atomic layer deposition (ALD); and

etching the material layer of the spacer to form the spacer in a self-aligned manner on the side surface of the dummy gate structure.

The thickness of the spacer is controlled by an ALD growth process, and the width of the metal zero layer is controlled by the thickness of the spacer.

In some cases, the low dielectric constant material forming the spacer includes SiOCN.

In the present application, the middle of line for forming the metal zero layer is performed prior to the zero interlayer dielectric process loop of the front end of line. An area for forming the metal zero layer is directly defined by the metal zero layer cut off layer formed in the selected area of the inter-gate trench, without selective etching of the zero interlayer dielectric. Therefore, the present application has the following beneficial technical effects:

1. The present application does not require etching of a selected area of the zero interlayer dielectric, so that the width of the metal zero layer can be fully defined by the width of the inter-gate trench in a self-aligned manner. In the prior art, when the selected area of the zero interlayer dielectric is etched to form an opening area of the zero interlayer dielectric, the width of the opening area of the zero interlayer dielectric is necessarily less than the width of the inter-gate trench. Therefore, the present application can increase a contact area between the metal zero layer and the source and drain regions at the bottom of the inter-gate trench, and can maximize the contact area between the metal zero layer and the source and drain regions at the bottom of the inter-gate trench, thus reducing a contact resistance of the source and drain regions and improving the device performance. As the process node shrinks, an embedded epitaxial layer is usually formed in the source and drain regions, and therefore the present application can reduce a contact area between the metal zero layer and the embedded epitaxial layer of the source and drain regions.

2. Since the present application does not require the etching of the selected area of the zero interlayer dielectric, a damage caused by a process of etching the zero interlayer dielectric to the bottom source and drain regions can be prevented, also reducing the contact resistance of the source and drain regions and thereby improving the device performance. When an embedded epitaxial layer is formed in the source and drain regions, the present application can avoid damage to the embedded epitaxial layer of the source and drain regions. A larger volume of the embedded epitaxial layer is more conducive to an increase in the mobility of channel carriers, thereby also improving the device performance.

In addition, since the present application does not require the etching of the selected area of the zero interlayer dielectric, a damage caused by the process of etching the zero interlayer dielectric to the spacer can be prevented, significantly reducing the risk of a short circuit between the metal zero layer and the metal gate and thereby improving the product yield.

3. The metal zero layer process loop of the present application is prior to the zero interlayer dielectric process loop, and is necessarily more prior to the metal gate process loop, such as an HKMG process. In this way, an annealing process of the metal silicide between the metal zero layer and the source and drain regions is performed before the HKMG process or is directly achieved by means of a thermal process of the HKMG process, so as to prevent a thermal process of the annealing process of the metal silicide between the metal zero layer and the source and drain regions from being superimposed into the HKMG process when the annealing process of the metal silicide between the metal zero layer and the source and drain regions in the existing process is performed after the HKMG process. Therefore, the present application can also reduce a thermal load of the HKMG process, reducing the fluctuation of a threshold voltage (Vt) of the device and thereby improving the stability of the threshold voltage.

4. In the present application, the width of the metal zero layer can be fully defined by the width of the inter-gate trench in a self-aligned manner, and the width of the inter-gate trench can be controlled by the width of the dummy gate structure and the thickness of the spacer on the side surface of the dummy gate structure. Therefore, the uniformity of the width of the metal zero layer can be significantly improved by growing the spacer using the ALD growth process.

5. In the present application, the process of forming the metal zero layer is performed earlier, so that the metal zero layer and the metal gate are both led out from the zero layer vias. In this way, the zero layer via connected to the metal gate and the zero layer via connected to the metal zero layer can be located in the same layer, reducing additional masks connected to the metal gate and thus significantly reducing the cost of masks.

In addition, since the zero layer via connected to the metal gate and the zero layer via connected to the metal zero layer are located in the same layer, the zero layer via connected to the metal gate and the zero layer via connected to the metal zero layer can be located on the same plane, thereby improving the device density and product performance. For example, in an SRAM, the dimension of a 6T bitcell in a Y direction can be reduced to transform the 6T bitcell into a 5T bitcell similar to a contact on active gate (COAG), thus improving the device density and improving the product performance.

### BRIEF DESCRIPTION OF THE DRAWINGS

The present application is described in detail below with reference to the drawings and specific implementations

FIG. 1 is a flowchart of an existing method for manufacturing a FinFET that includes a process of manufacturing a metal zero layer.

FIGS. 2A-2H are schematic structural diagrams of device sections in steps of the manufacturing method corresponding to FIG. 1.

FIG. 3 is a flowchart of a method for manufacturing a FinFET that includes a process of manufacturing a metal zero layer according to an embodiment of the present application.

FIGS. 4A-4L are schematic structural diagrams of device sections in steps of the manufacturing method corresponding to FIG. 3.

FIG. 5 is a schematic structural diagram of a device top view in step 2 of the manufacturing method corresponding to FIG. 3.

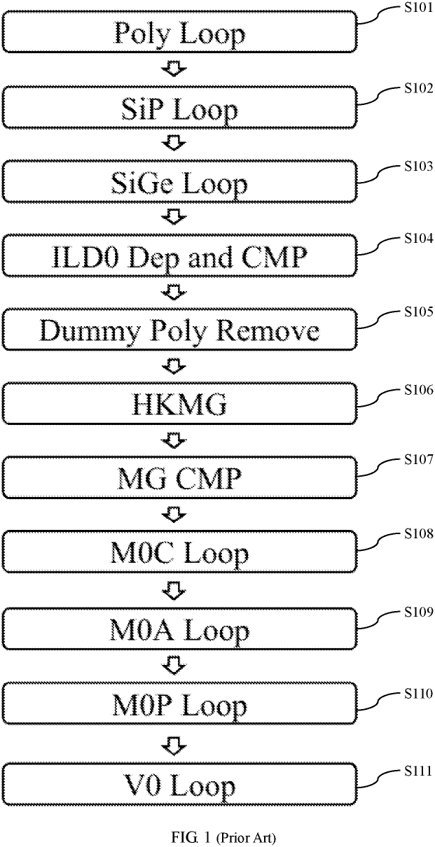

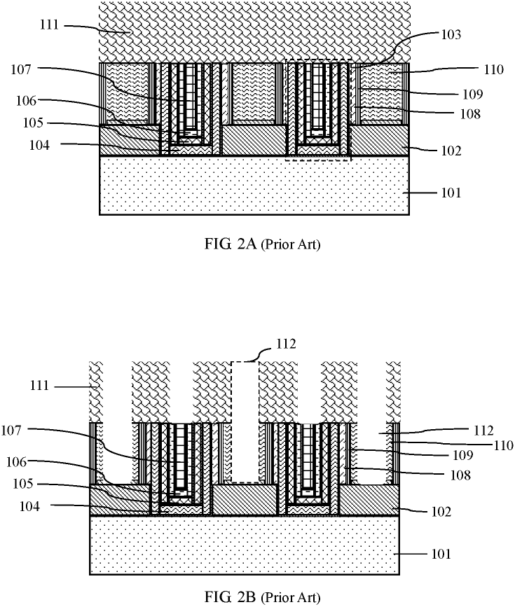

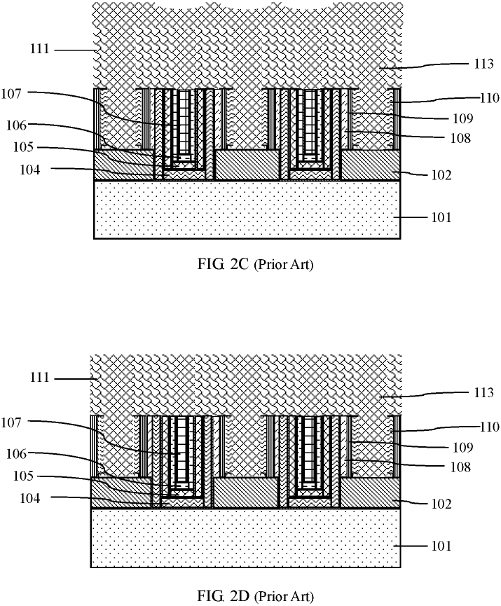

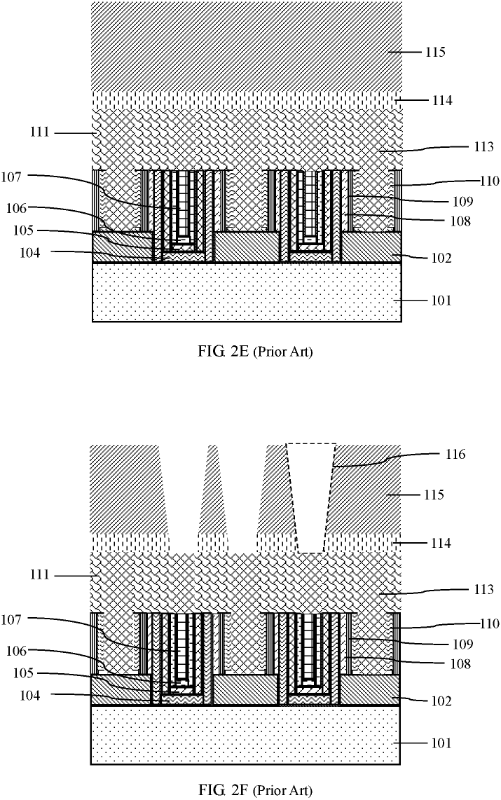

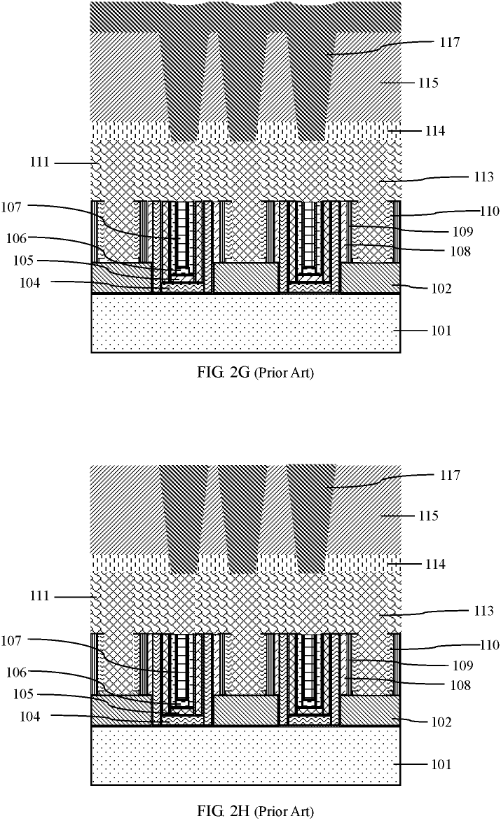

### DETAILED DESCRIPTION OF THE DISCLOSURE

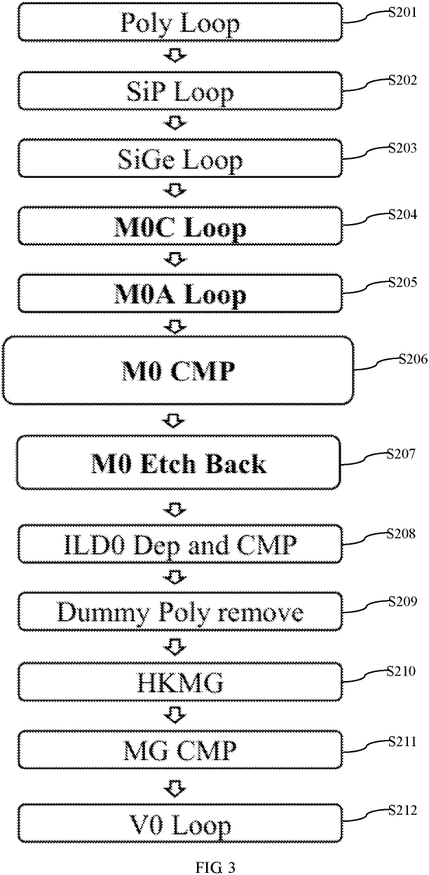

In the embodiments of the present application, a method of manufacturing a metal zero layer 209 is combined with a manufacturing process of an entire semiconductor device for explanation, taking a FinFET as an example of the semiconductor device, while in other embodiments, the semiconductor device may also be a GAAFET. FIG. 3 is a flowchart of a method for manufacturing a FinFET that includes a process of manufacturing a metal zero layer 209 according to an embodiment of the present application. FIG. 3 also shows the front end of line from a dummy polysilicon gate to a metal gate. The middle of line corresponding to the metal zero layer 209 is inserted into the front end of line, and FIG. 3 also shows the back end of line corresponding to a zero layer via 220. The method for manufacturing a FinFET according to this embodiment of the present application includes the following steps.

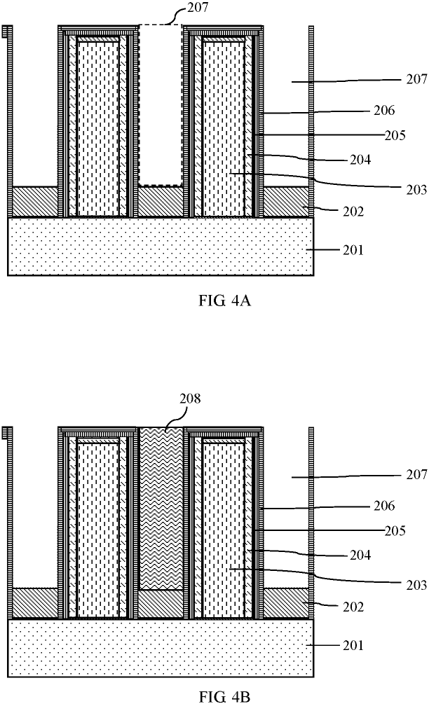

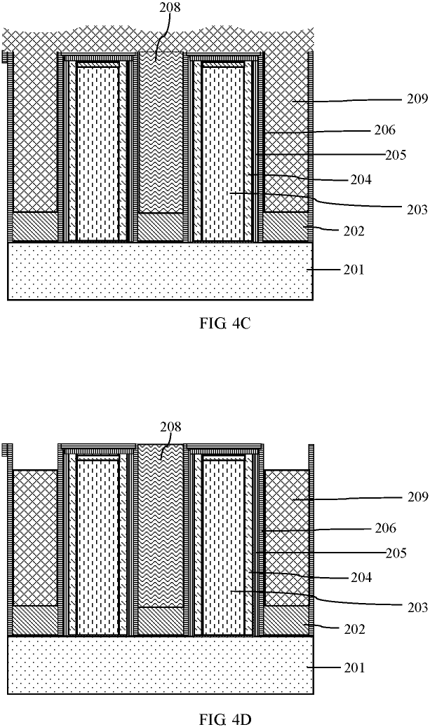

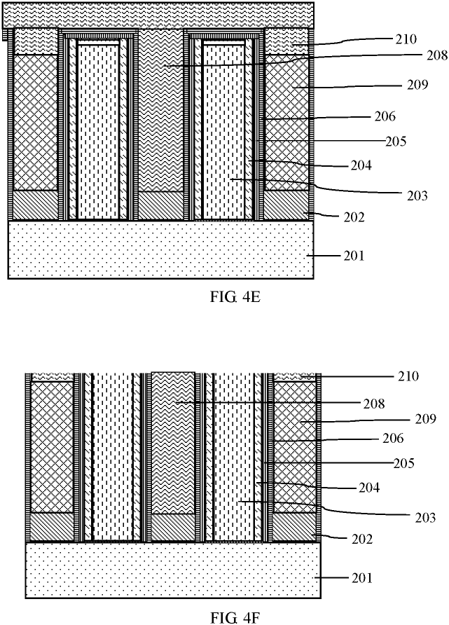

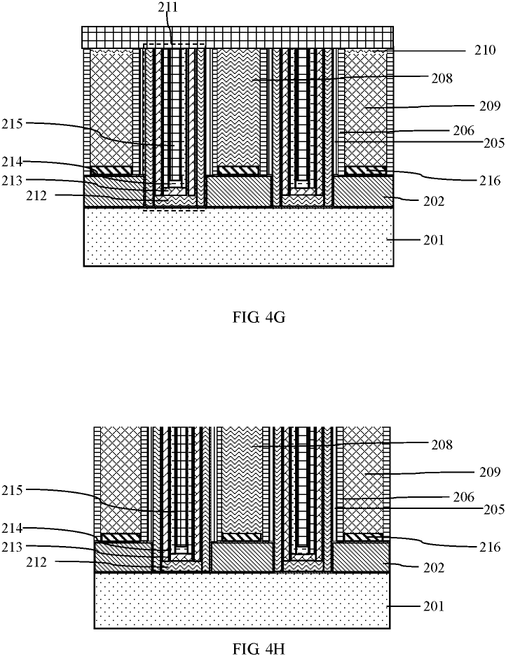

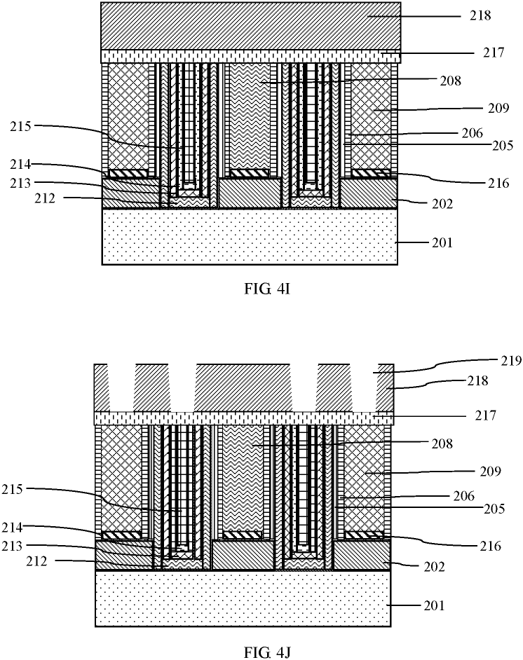

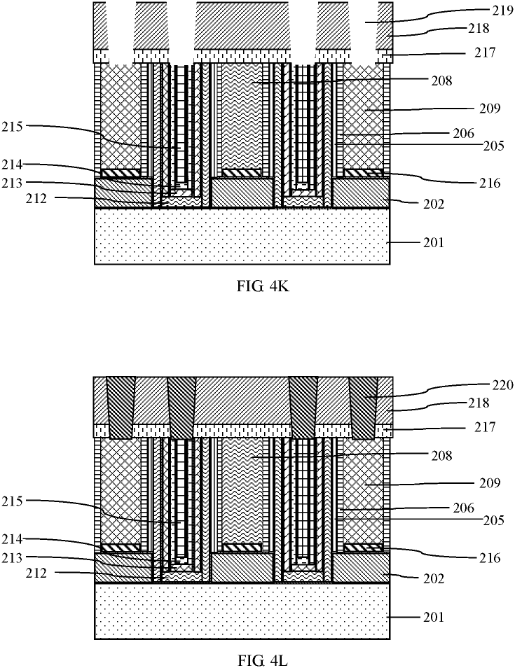

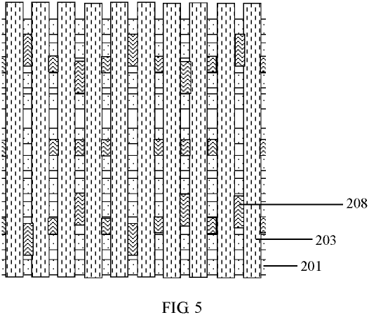

Step 1. Referring to FIG. 4A, a semiconductor substrate that undergoes a source and drain formation process of the front end of line is provided, wherein source and drain regions are formed on two sides of a dummy gate structure, a spacer is formed on the side surface of the dummy gate structure, a hard mask layer is formed on the top of the dummy gate structure, a plurality of the dummy gate structures are formed on the semiconductor substrate, and an inter-gate trench 207 is formed in an area between the dummy gate structures.

In this embodiment of the present application, a fin 201 is formed on the semiconductor substrate by performing patterned etching of the semiconductor substrate. An embedded epitaxial layer 202 is formed in the source and drain regions.

The dummy gate structure is usually composed of a dummy gate dielectric layer and a dummy polysilicon gate 203, so a process loop of the dummy gate structure is represented by poly loop.

In order to improve the carrier mobility of the device, a stress enhancing structure such as the embedded epitaxial layer 202 is often formed to increase the stress in a channel area. A process of forming the embedded epitaxial layer 202 includes: forming a groove on two sides of the dummy gate structure in a self-aligned manner, and then filling the groove with the embedded epitaxial layer 202. Generally, both an NMOS and a PMOS are integrated on the semiconductor substrate. The embedded epitaxial layer 202 of the NMOS adopts SiP, and a SiP Loop is performed only in an area for forming the NMOS. The embedded epitaxial layer 202 of the PMOS adopts SiGe. A SiGe Loop is performed only in an area for forming the PMOS.

Step 1 includes the following steps in FIG. 3.

Step S201: The Poly Loop is performed to form the dummy gate structure. The dummy gate structure needs to be defined by a hard mask layer. After formation of the dummy gate structure, a step of forming a spacer is performed. In FIG. 4A, the spacer includes an oxide layer 204 and a low dielectric constant layer 205. The oxide layer 204 of the spacer can be formed by means of oxidization of the dummy polysilicon gate 203. The low dielectric constant layer 205 of the spacer can be formed by means of ALD growth. After the low dielectric constant layer 205 with a required thickness is grown by the ALD, etching is performed to form the spacer on the side surface of the dummy gate structure in a self-aligned manner.

The ALD process can precisely control the thickness of the low dielectric constant layer 205. Therefore, in this embodiment of the present application, the thickness of the spacer is controlled by the ALD growth process, and the width of the subsequently formed metal zero layer 209 is controlled by the thickness of the spacer.

The material of the low dielectric constant layer 205 includes SiOCN.

Step S202. The SiP Loop is performed.

Step S203. The SiGe Loop is performed.

The sequence of step S202 and step S203 can be interchanged.

A step of forming a CESL 206 is generally performed before the subsequent process.

Step 2. Referring to FIG. 4B, a cut-off layer 208 of metal zero layer 209 is formed in a selected area of the inter-gate trench 207, the cut-off layer 208 of metal zero layer 209 being composed of a dielectric layer.

The cut-off layer 208 of metal zero layer 209 is used to cut off the subsequently formed metal zero layer 209. Therefore, a process of forming the cut-off layer 208 of metal zero layer 209 corresponds to an MOC loop in step S204 shown in FIG. 3.

In this embodiment of the present application, the dielectric layer of the cut-off layer 208 of metal zero layer 209 is a low-temperature oxide layer.

Sub-steps of forming a patterned structure of the cut-off layer 208 of metal zero layer 209 include the following.

Step 21. A first photolithography process is performed, the first photolithography process including: sequentially applying a spin on carbon layer and a photoresist, the spin on carbon layer fully filling the inter-gate trench 207, and exposure and development are performed to pattern the photoresist.

Step 22. A first etching process is performed, the first etching fully removing the spin on carbon layer in an open area of the patterned photoresist and fully consuming the photoresist.

Step 23. The low-temperature oxide layer is formed to fully fill the inter-gate trench 207 in an area where the spin on carbon layer is removed.

In this embodiment of the present application, step 23 includes the following sub-steps:

A deposition process of the low-temperature oxide layer is performed. The top surface of the low-temperature oxide layer is higher than the top surface of the inter-gate trench 207, and the low-temperature oxide layer extends outside the inter-gate trench 207.

The low-temperature oxide layer is etched, so that the low-temperature oxide layer remains only in the inter-gate trench 207 and the top surface of the low-temperature oxide layer is level with the top surface of the inter-gate trench 207.

Step 24. A second etching process is performed to remove the carbon coating in the inter-gate trench 207 outside the low-temperature oxide layer.

FIG. 5 is a schematic structural diagram of a device top view in step 2 of the manufacturing method corresponding to FIG. 3. FIG. 5 shows that a plurality of fins 201 arranged in parallel are formed on the semiconductor substrate. In a top view, the dummy polysilicon gate 203 is perpendicular to the fin 201, and the dummy polysilicon gate 203 spans a plurality of fins 201.

The cut-off layer 208 of metal zero layer 209 is selectively arranged in a partial area of the inter-gate trench 207. Step 21 to step 24 are represented by LE+LTO+E, wherein L in LE represents the first photolithography process, and E in LE represents the first etching process; LTO represents the process of forming the low-temperature oxide layer; the last E represents the second etching process. When the second etching process adopts wet etching, the second etching process can also be represented by wet strip.

In order to form a plurality of the metal zero layer 209 cut-off layers 208 or obtain the cut-off layer 208 of metal zero layer 209 of a smaller dimension, in some embodiments, step 21 to step 24 in step 2 are performed circularly for a plurality of times, that is, LE+LTO+E is performed for a plurality of times.

Step 3. Referring to FIG. 4C, the metal zero layer 209 is formed in the inter-gate trench 207 outside the cut-off layer 208 of metal zero layer 209.

Referring to FIG. 4D, the metal zero layer 209 is etched back to make the top surface of the metal zero layer 209 lower than the top surface of the dummy gate structure.

In this embodiment of the present application, the metal zero layer 209 is formed only at the top of the source and drain regions, that is, only the active area metal zero layer 209 is formed while no gate metal zero layer is formed. Therefore, step 3 is implemented by the following steps corresponding to FIG. 3.

Step S205. Referring to FIG. 4C, an MOA Loop is performed. The metal zero layer 209 is first formed in the MOA Loop. The material of the metal zero layer 209 is Co. The metal zero layer 209 is formed by means of an electroplating process. A step of forming a first barrier layer and a second seed layer is performed before formation of the metal zero layer 209, and the first barrier layer is used to block Co diffusion of the metal zero layer 209.

Step S206. M0 CMP is performed. Generally, the metal zero layer 209 extends to the outside of the inter-gate trench 207 after being formed. Therefore, CMP is required to make the metal zero layer 209 level with the top surface of the inter-gate trench 207.

Step S207. Referring to FIG. 4D, M0 Etch Back is performed, so as to make the top surface of the metal zero layer 209 lower than the top surface of the dummy gate structure, i.e., the top surface of the dummy polysilicon gate 203. In some embodiments, the metal zero layer 209, the first barrier layer, and the second seed layer are etched back by means of a wet etching process.

Step 4. Referring to FIG. 4E, a second oxide layer 210 is formed, the second oxide layer 210 fully filling the inter-gate trench 207 on the top surface of the metal zero layer 209.

Referring to FIG. 4F, a planarization process is performed to make the top surface of the second oxide layer 210 level with the top surface of the dummy gate structure, and the hard mask layer on the top surface of the dummy gate structure is removed.

In this embodiment of the present application, the second oxide layer 210 is similar to the zero interlayer dielectric in the existing method. Therefore, step 4 is implemented by step S208 in FIG. 3. Step S208 is represent by ILD0 Dep and CMP.

Step 5. Referring to FIG. 4G, the dummy gate structure is removed, and a second gate structure 211 is formed in an area where the dummy gate structure is removed, the second gate structure 211 being formed by stacking a gate dielectric layer and a metal gate.

In this embodiment of the present, the second gate structure 211 adopts HKMG, the gate dielectric layer includes a high dielectric constant material layer 212 and a bottom barrier layer 213, and the metal gate includes a work function metal layer 214 and a metal conductive material layer 215 which are stacked.

Step 5 is implemented by the following steps in FIG. 3.

Step S209. Dummy ploy remove is performed to remove the dummy gate structure.

Step S210. HKMG is formed. In some embodiments, the metal of the metal conductive material layer 215 is tungsten. After tungsten growth, in addition to filling an area where the dummy gate structure is removed, the tungsten material of the metal conductive material layer 215 extends beyond the area where the dummy gate structure is removed.

As a process of forming the gate dielectric layer adopts a high temperature, for example, a process of forming the high dielectric constant material layer 212 and an interface layer between the high dielectric constant material layer 212 and the bottom semiconductor substrate adopts a high temperature, in some example embodiments, a thermal process in a process of forming the second gate structure 211 is used to achieve a silicification reaction between the metal zero layer 209 and bottom silicon and form a metal silicide 216.

Step S210. MG CMP is performed, referring to FIG. 4H, so as to remove the work function metal layer 214 and the metal conductive material layer 215 outside the area where the dummy gate structure is removed and regulate the height of the second gate structure 211 to a target value. In this case, the second oxide layer 210 is fully removed.

The method further includes the following after step 5.

A third oxide layer 218 is formed. The third oxide layer 218 is an interlayer dielectric penetrated by the zero layer via 220. In some embodiments, the third oxide layer 218 is formed by means of PECVD.

In some example embodiments, a step of forming a cap layer 217 is performed before formation of the third oxide layer 218. The cap layer 217 is used to protect the metal zero layer 209 and prevent the metal zero layer 209 from oxidation and loss. In some embodiments, the material of the cap layer 217 is SiN.

The third oxide layer 218 of the selected area is etched to form an opening 219 of the zero layer via 220. The opening 219 of the zero layer via 220 is located at the top of the selected area on the top surface of the metal zero layer 209 and at the top of the selected area on the top surface of the second gate structure 211.

A process of forming the opening 219 of the zero layer via 220 includes the following.

Referring to FIG. 4J, the third oxide layer 218 is etched first. In order to obtain the opening 219 with a relatively small dimension, in some embodiments, LELE is performed circularly. LELE represents double photolithography plus etching, wherein L represents photolithography, and E represents etching.

Subsequently, referring to FIG. 4K, after etching of the third oxide layer 218 is, the cap layer 217 is etched so that the opening 219 of the zero layer via 220 exposes the bottom metal zero layer 209 or the top surface of the metal gate. The etching of the cap layer 217 is a liner remove (LRM) process.

Referring to FIG. 4L, the opening 219 of the zero layer via 220 is filled with a metal to form the zero layer via 220. The metal zero layer 209 is in contact with the top zero layer via 220, and the metal gate is in contact with the top zero layer via 220.

In some embodiments, the metal material of the zero layer via 220 includes tungsten.

In this embodiment of the present application, the middle of line for forming the metal zero layer 209 is performed prior to the zero interlayer dielectric process loop of the front end of line. An area for forming the metal zero layer 209 is directly defined by the metal zero layer 209 cut off layer 208 formed in the selected area of the inter-gate trench 207, without selective etching of the zero interlayer dielectric. Therefore, this embodiment of the present application has the following beneficial technical effects:

1. This embodiment of the present application does not require etching of a selected area of the zero interlayer dielectric, so that the width of the metal zero layer 209 can be fully defined by the width of the inter-gate trench 207 in a self-aligned manner. In the prior art, when the selected area of the zero interlayer dielectric is etched to form an opening area of the zero interlayer dielectric, the width of the opening area of the zero interlayer dielectric is necessarily less than the width of the inter-gate trench 207. Therefore, this embodiment of present application can increase a contact area between the metal zero layer 209 and the source and drain regions at the bottom of the inter-gate trench 207, and can maximize the contact area between the metal zero layer 209 and the source and drain regions at the bottom of the inter-gate trench 207, thus reducing a contact resistance of the source and drain regions and improving the device performance. As the process node shrinks, an embedded epitaxial layer is usually formed in the source and drain regions, and therefore the present application can reduce a contact area between the metal zero layer 209 and the embedded epitaxial layer of the source and drain regions.

2. Since this embodiment of the present application does not require the etching of the selected area of the zero interlayer dielectric, a damage caused by a process of etching the zero interlayer dielectric to the bottom source and drain regions can be prevented, also reducing the contact resistance of the source and drain regions and thereby improving the device performance. When an embedded epitaxial layer is formed in the source and drain regions, this embodiment of the present application can avoid a damage to the embedded epitaxial layer of the source and drain regions. A larger volume of the embedded epitaxial layer is more conducive to an increase in the mobility of channel carriers, thereby also improving the device performance.

In addition, since this embodiment of the present application does not require the etching of the selected area of the zero interlayer dielectric, a damage caused by the process of etching the zero interlayer dielectric to the spacer can be prevented, significantly reducing the risk of a short circuit between the metal zero layer 209 and the metal gate and thereby improving the product yield.

3. The metal zero layer process loop of this embodiment of the present application is prior to the zero interlayer dielectric process loop, and is necessarily more prior to the metal gate process loop, such as an HKMG process. In this way, an annealing process of the metal silicide 216 between the metal zero layer 209 and the source and drain regions is performed before the HKMG process or is directly achieved by means of a thermal process of the HKMG process, so as to prevent a thermal process of the annealing process of the metal silicide 216 between the metal zero layer 209 and the source and drain regions from being superimposed into the HKMG process when the annealing process of the metal silicide 216 between the metal zero layer 209 and the source and drain regions in the existing process is performed after the HKMG process. Therefore, this embodiment of the present application can also reduce a thermal load of the HKMG process, reducing the fluctuation of a threshold voltage (Vt) of the device and thereby improving the stability of the threshold voltage.

4. In this embodiment of the present application, the width of the metal zero layer 209 can be fully defined by the width of the inter-gate trench 207 in a self-aligned manner, and the width of the inter-gate trench 207 can be controlled by the width of the dummy gate structure and the thickness of the spacer on the side surface of the dummy gate structure. Therefore, the uniformity of the width of the metal zero layer 209 can be significantly improved by growing the spacer using the ALD growth process.

5. In this embodiment of the present application, the process of forming the metal zero layer 209 is performed earlier, so that the metal zero layer 209 and the metal gate are both led out from the zero layer vias 220. In this way, the zero layer via 220 connected to the metal gate and the zero layer via 220 connected to the metal zero layer 209 can be located in the same layer, reducing additional masks connected to the metal gate and thus significantly reducing the cost of masks.

In addition, since the zero layer via 220 connected to the metal gate and the zero layer via 220 connected to the metal zero layer 209 are located in the same layer, the zero layer via 220 connected to the metal gate and the zero layer via 220 connected to the metal zero layer 209 can be located on the same plane, thereby improving the device density and product performance. For example, in an SRAM, the dimension of a 6T bitcell in a Y direction can be reduced to transform the 6T bitcell into a 5T bitcell similar to a contact on active gate (COAG), thus improving the device density and improving the product performance.

The present application is described in detail above via specific embodiments, which, however, do not intended to limit the present application. Without departing from the principle of the present application, those skilled in the art can also make many other changes and improvements, which shall also be considered as the scope of protection the present application.

What is claimed is:

1. A method for manufacturing a metal zero layer, comprising the following steps:
step 1, providing a semiconductor substrate that undergoes a source and drain formation process of the front end of line, wherein source and drain regions are formed on two sides of a dummy gate structure, a spacer is formed on the side surface of the dummy gate structure, a hard mask layer is formed on the top of the dummy gate structure, a plurality of the dummy gate structures are formed on the semiconductor substrate, and an inter-gate trench is formed in an area between the dummy gate structures;
step 2, forming a cut-off layer of metal zero layer in a selected area of the inter-gate trench, the cut-off layer of metal zero layer being composed of a dielectric layer;
step 3, forming a metal zero layer in the inter-gate trench outside the cut-off layer of metal zero layer, and etching back the metal zero layer to make the top surface of the metal zero layer lower than the top surface of the dummy gate structure;
step 4, forming a second oxide layer, the second oxide layer fully filling the inter-gate trench on the top surface of the metal zero layer, performing a planarization process to make the top surface of the second oxide layer level with the top surface of the dummy gate structure, and removing the hard mask layer on the top surface of the dummy gate structure; and
step 5, removing the dummy gate structure, and forming a second gate structure in an area where the dummy gate structure is removed, the second gate structure being formed by stacking a gate dielectric layer and a metal gate.

2. The method for manufacturing the metal zero layer according to claim 1, wherein in step 2, the dielectric layer of the cut-off layer of metal zero layer is a low-temperature oxide layer.

3. The method for manufacturing the metal zero layer according to claim 2, wherein in step 2, sub-steps of forming a patterned structure of the cut-off layer of metal zero layer comprise:
step 21, performing a first photolithography process, the first photolithography process comprising: sequentially applying a spin on carbon layer and a photoresist, the spin on carbon layer fully filling the inter-gate trench, and performing exposure and development to pattern the photoresist;
step 22, performing a first etching process, the first etching fully removing the spin on carbon layer in an open area of the patterned photoresist and fully consuming the photoresist;
step 23, forming the low-temperature oxide layer to fully fill the inter-gate trench in an area where the spin on carbon layer is removed; and
step 24, performing a second etching process to remove the carbon coating in the inter-gate trench outside the low-temperature oxide layer.

4. The method for manufacturing the metal zero layer according to claim 3, wherein in step 2, step 21 to step 24 are performed circularly for a plurality of times.

5. The method for manufacturing the metal zero layer according to claim 3, wherein step 23 comprises the following sub-steps:
performing a deposition process of the low-temperature oxide layer, the top surface of the low-temperature oxide layer being higher than the top surface of the inter-gate trench, and the low-temperature oxide layer extending outside the inter-gate trench; and
etching the low-temperature oxide layer, so that the low-temperature oxide layer remains only in the inter-gate trench and the top surface of the low-temperature oxide layer is level with the top surface of the inter-gate trench.

6. The method for manufacturing the metal zero layer according to claim 1, wherein in step 3, a material of the metal zero layer is Co;
the metal zero layer is formed by means of an electroplating process; and
a step of forming a first barrier layer and a second seed layer is performed before formation of the metal zero layer, the first barrier layer being used to block Co diffusion of the metal zero layer.

7. The method for manufacturing the metal zero layer according to claim 6, wherein the metal zero layer, the first barrier layer, and the second seed layer are etched back by means of a wet etching process.

8. The method for manufacturing the metal zero layer according to claim 1, after step 5, further comprising:
forming a third oxide layer;
etching the third oxide layer in the selected area to form an opening of a zero layer via, the opening of the zero layer via being located at the top of the selected area on the top surface of the metal zero layer and being located at the top of the selected area on the top surface of the second gate structure; and
filling the opening of the zero layer via with a metal to form the zero layer via, the metal zero layer being in contact with the top zero layer via, and the metal gate being in contact with the top zero layer via.

9. The method for manufacturing the metal zero layer according to claim 8, wherein before formation of the third oxide layer, further comprising a step of forming a cap layer, the cap layer being used to protect the metal zero layer and prevent the metal zero layer from oxidation and loss; wherein
in a process of forming the opening of the zero layer via, after etching of the third oxide layer, the cap layer is etched so that the opening of the zero layer via exposes the bottom metal zero layer or the top surface of the metal gate.

10. The method for manufacturing the metal zero layer according to claim 9, wherein a material of the cap layer is silicon nitride.

11. The method for manufacturing the metal zero layer according to claim 8, wherein the metal material of the zero layer via comprises tungsten.

12. The method for manufacturing the metal zero layer according to claim 1, wherein in step 5, the gate dielectric layer comprises a high dielectric constant material layer; and
the metal gate comprises a metal work function layer and a metal conductive material layer which are stacked in sequence.

13. The method for manufacturing the metal zero layer according to claim 12, wherein the semiconductor substrate comprises a silicon substrate.

14. The method for manufacturing the metal zero layer according to claim 13, wherein in step 1, the source and drain formation process further comprises a step of forming an embedded epitaxial layer, and the source and drain regions are formed in the embedded epitaxial layer.

15. The method for manufacturing the metal zero layer according to claim 14, wherein in an area for forming a PMOS, a material of the embedded epitaxial layer comprises SiGe; and in an area for forming an NMOS, a material of the embedded epitaxial layer comprises SiP.

16. The method for manufacturing the metal zero layer according to claim 15, wherein in step 5, a thermal process in a process of forming the second gate structure is used to achieve a silicification reaction between the metal zero layer and bottom silicon and form a metal silicide.

17. The method for manufacturing the metal zero layer according to claim 1, wherein in step 1, a material of the spacer comprises a low dielectric constant material;
a process of forming the spacer comprises: growing a material layer of the spacer by means of atomic layer deposition (ALD); and
etching the material layer of the spacer to form the spacer in a self-aligned manner on the side surface of the dummy gate structure; wherein
a thickness of the spacer is controlled by an ALD growth process, and a width of the metal zero layer is controlled by a thickness of the spacer.
